(19) United States
(12) Patent Application Publication
(10) Pub. No.: US 2011/0032640 A1
(43) Pub. Date: Feb. 10, 2011

(54) MULTI-LAYER, THIN FILM OVERCOAT FOR MAGNETIC MEDIA DISK

(75) Inventors: Bruno Marchon, Palo Alto, CA (US); Daryl J. Pocker, San Jose, CA (US); Ricardo Ruiz, San Bruno, CA (US); Richard L. White, Los Altos, CA (US)

Correspondence Address: Larson Newman & Abel, LLP, 5914 West Courtyard Drive, Suite 200, Austin, TX, 78730, US

(73) Assignee: Hitachi Global Storage Technologies Netherlands B.V., Amsterdam (NL)

(21) Appl. No.: 12/538,312

(22) Filed: Aug. 10, 2009

(51) Int. Cl. G11B 5/187; G11B 5/66; B05D 5/12; C23C 14/34; C23C 14/36

(52) U.S. Cl. 360/122; 428/827; 427/127; 204/192.1; 204/192.15; G9B/5.104

(57) ABSTRACT

A thin film magnetic disk overcoat for perpendicular magnetic recording media comprises three layers. The initial layer comprises a dense mixture of both SiCₓ and SiN_{y} compounds. The intermediate layer is a relatively dense high energy carbon process and the outer layer is sputtered CNₓ. The overall thickness of the overcoat is less than about 35 Å. The overcoat has the desired lubricant interaction with the elements that comprise the magnetic layers adjacent to the overcoat. Adjusting the SiC/SiN ratio in the overcoat eliminates potential negative interaction with the magnetic layers of the disk.

### BACKGROUND OF THE INVENTION

1. Technical Field

The present invention relates in general to disk overcoats and, in particular, to an improved system, method and apparatus for a multi-layer, thin film overcoat for perpendicular magnetic recording media disks.

2. Description of the Related Art

Hard disk drives provide data storage for data processing systems in computers and servers. Disk drives are also becoming increasingly pervasive in media players, digital recorders, and other personal devices. Advances in disk drive technology have made it possible for a user to store an immense amount of digital information on an increasingly small disk, and to selectively retrieve and alter portions of such information almost instantaneously. Particularly, recent developments have simplified disk drive manufacturing while yielding increased track densities, thus promoting increased data storage capabilities at reduced costs.

Hard disk drives rotate high precision media, such as an aluminum or glass disk coated on both sides with thin films, to store information in the form of magnetic patterns. Electromagnetic read/write heads suspended or floating only fractions of micro inches above the disk are used to either record information onto the thin film media, or read information from it.

A read/write head may write information to the disk by creating an electromagnetic field to orient a cluster of magnetic grains, known as a bit, in one direction or the other. In longitudinal magnetic recording media applications, a magnetic recording layer has a magnetic c-axis (or easy axis) parallel to the disk plane. As the disk drive industry is transitioning to perpendicular recording technology, adjustments are being made to adapt the disk media so that the magnetic easy axis (crystallographic c-axis) of the cobalt alloy recording layers grow perpendicular to the disk plane. Hexagonal close packed cobalt alloys are typically used as a magnetic recording layer for perpendicular recording.

To read information, magnetic patterns detected by the read/write head are converted into a series of pulses that are sent to the logic circuits to be converted to binary data and processed by the rest of the system. To write information, a write element located on the read/write head generates a magnetic write field that travels vertically through the magnetic recording layer and returns to the write element through a soft underlayer.

An overcoat in the form of a thin film on the perpendicular magnetic recording (PMR), longitudinal or patterned media provides both corrosion and wear resistance. The thickness of the overcoat must be minimal to provide these functions since it results in separation between the recording media and the read and write elements in the head. The recording performance of PMR media is strongly affected by this separation distance (about 0.5 order in error rate/nm separation).

Increasing the density of the overcoat material is a recognized technique for providing improved corrosion resistance with thinner overcoat layers. The SiCₓN_{y} overcoat material disclosed herein in accordance with the invention is significantly denser than the carbon-based overcoats currently in use. An important additional requirement for the overcoat is that it does not negatively interact with the magnetic media through chemical reaction to degrade the magnetic layer recording performance.

U.S. Pat. No. 6,136,421 describes a silicon nitride/CNₓ (COC) bi-layer applied as an overcoat for thin film disk media. However, the solution disclosed in that patent produces a negative interaction with the underlying media. The structure disclosed in that patent also is only applicable to relatively thick overcoats compared to those needed for modern disk structure. The overcoat structure described herein in accordance with the invention eliminates the undesirable magnetic interaction and utilizes a lubricant interaction layer that is beneficial for modern disk overcoats.

### SUMMARY OF THE INVENTION

Embodiments of a system, method, and apparatus for a thin film magnetic disk overcoat for magnetic recording media are disclosed. The overcoat may comprise three layers, including an initial layer comprising a dense mixture of both SiCₓ and SiN_{y} compounds, in some embodiments. The overcoat also may include an intermediate layer of a relatively dense high energy carbon process and an outer layer of sputtered CNₓ.

In some embodiments, the thickness of the individual layers may be adjusted to provide the overcoat with an overall thickness that is less than about 35 Å. The overcoat has the desired interaction with the disk elements that comprise the magnetic layer adjacent to the overcoat. The adjustment of the SiC/SiN ratio eliminates any potential negative interaction with the disk. Although carbon-only based overcoats do not negatively interact with magnetic materials, they have reduced density compared to the invention and do not have sufficient corrosion resistance at comparable thickness.

The tri-layer structure that comprises the overcoat in accordance with the invention may be provided with an initial layer of reactively-sputtered SiCₓN_{y}. This layer is typically deposited with a pulsed DC power supply and sputter process, or RF sputtering, both of which are suitable for sputtering compounds that are highly resistive. These specialized techniques avoid the build-up of charge on insulating regions of the target. If these insulating regions are not discharged before the critical voltage is developed, arcing can occur during the deposition process which produces undesirable levels of particle defects in the sputtered layers. The nitrogen that reacts with the sputtered silicon is present as a mixture of Ar+N₂ in the sputter working gas. The SiC is formed by reaction of the non-nitrided Si with the subsequently deposited carbon layers.

In some embodiments, the second or intermediate layer of the tri-layer comprises a relatively thin carbon layer deposited by a high energy deposition process, typically ion beam deposition. The second layer provides a dense barrier to prevent oxidation of the SiCₓN_{y} layer. Additionally, it also provides carbon for reaction with the unbonded Si in the SiCₓN_{y} layer. Finally, an even thinner sputtered layer of CNₓ may be deposited over the ion beam layer. The sputtered CNₓ layer provides the surface concentration of nitrogen needed to optimize the interaction with the topical lubricant applied to the thin film disk surface.

The foregoing and other objects and advantages of the present invention will be apparent to those skilled in the art, in view of the following detailed description of the present invention, taken in conjunction with the appended claims and the accompanying drawings.

### BRIEF DESCRIPTION OF THE DRAWINGS

So that the manner in which the features and advantages of the present invention are attained and can be understood in more detail, a more particular description of the invention briefly summarized above may be had by reference to the embodiments thereof that are illustrated in the appended drawings. However, the drawings illustrate only some embodiments of the invention and therefore are not to be considered limiting of its scope as the invention may admit to other equally effective embodiments.

FIG. 1 is a schematic drawing of one embodiment of a media overcoat constructed in accordance with the invention;

FIG. 2 is a plot of accelerated temperature and humidity corrosion testing for various types of overcoated media;

FIG. 3 is a plot correlating magnetic property degradation with SiC/SiN ratio;

FIG. 4 is a plot of intermediate layer thickness to avoid failure in high temperature and humidity environments;

FIG. 5 is a schematic diagram of a hard disk drive constructed in accordance with the invention; and

FIG. 6 is a high level flow diagram of one embodiment of a method constructed in accordance with the invention.

### DETAILED DESCRIPTION OF THE INVENTION

Furthermore, the described features, structures, or characteristics of the invention may be combined in any suitable manner in one or more embodiments. In the following description, numerous specific details are disclosed to provide a thorough understanding of embodiments of the invention. One skilled in the relevant art will recognize, however, that the invention may be practiced without one or more of the specific details, or with other methods, components, materials, and so forth. In other instances, well known structures, materials, or operations are not shown or described in detail to avoid obscuring aspects of the invention.

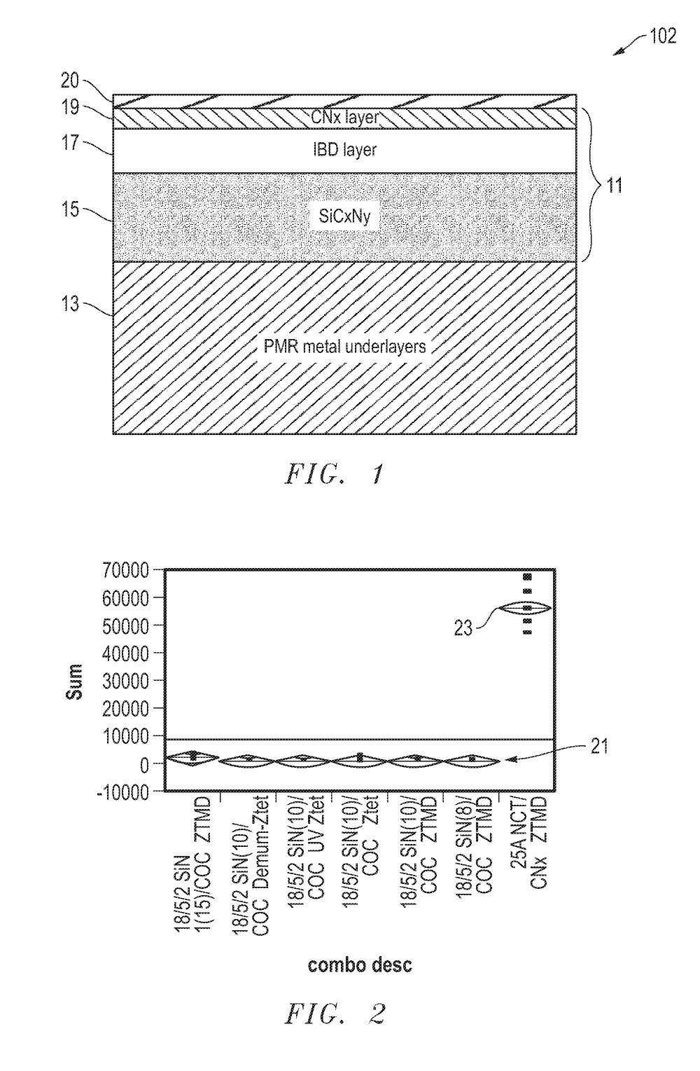

Referring to FIGS. 1-6, embodiments of a system, method and apparatus for a thin film magnetic disk overcoat for perpendicular magnetic recording media in hard disk drives are disclosed. FIG. 1 schematically illustrates one embodiment of a disk 102 having a structure of the overcoat 11 on underlayers 13 thereof, and is constructed in accordance with the invention. In some embodiments, the overcoat 11 comprises three layers, including an initial or base layer 15, an intermediate layer 17, an outer layer 19, and a topical lubricant 20. Composition, materials and fabrication of the overcoat will be more fully described in the following paragraphs.

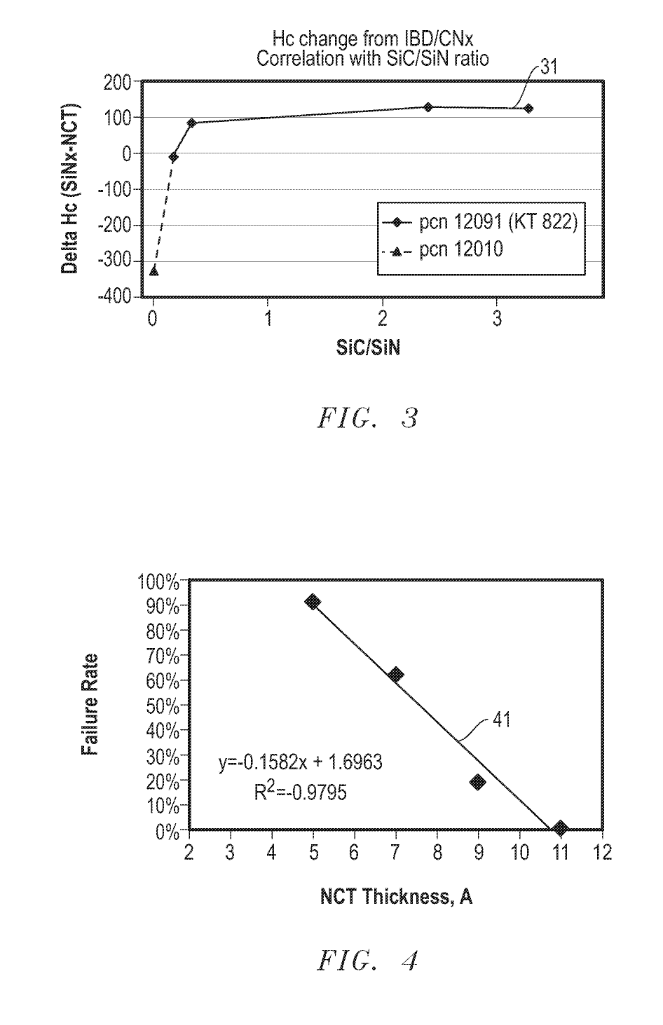

Improvements in the corrosion resistance of the overcoat are depicted in FIG. 2. The data in this drawing depicts the number of corrosion site defects (see y-axis) found on the surfaces of disk structures after the disks have been exposed to high temperature and humidity (i.e., 65° C. and 90% RH). Included in the drawing are corrosion results for different process options, as well as a range of potential topical lubricants. For the disks 21 coated with the SiCₓN_{y}/IBD/CNₓ type overcoat, the corrosion count was acceptably low and substantially lower than conventional C:H/CNₓ overcoat technology (e.g., 25 Å NCT/CNₓ ZTMD), which is depicted as disk 23.

FIG. 3 is a plot 31 that illustrates the impact of designing the base layer 15 (FIG. 1) of the overcoat 11 with desirable ratios of SiC/SiN. The dynamic control of the partial pressure of N₂ affects the reactive deposition of SiN. If the N₂ partial pressure used during deposition is too high, then the overcoat 11 is predominantly SiN and excess N₂ reacts with boron in the underlying magnetic layers to form BN. This degrades the magnetic performance as is evident by the reduction in magnetic coercivity. Conversely, if the N₂ partial pressure during deposition is too low, then there is excessive unreacted Si present in the base overcoat layer 15, which reacts with the underlying magnetic layers 13 to form silicides. This also degrades the magnetic performance as it increases magnetic coercivity. The ratios of the SiCₓ to SiN_{y} are determined by the fractions of Si atoms bound to C and N as determined by, e.g., X-ray Photoelectron Spectroscopy (XPS). This characterization technique differentiates the Si (C bound) from the Si (N bound) by careful determination or analysis of the Si photoelectron binding energy.

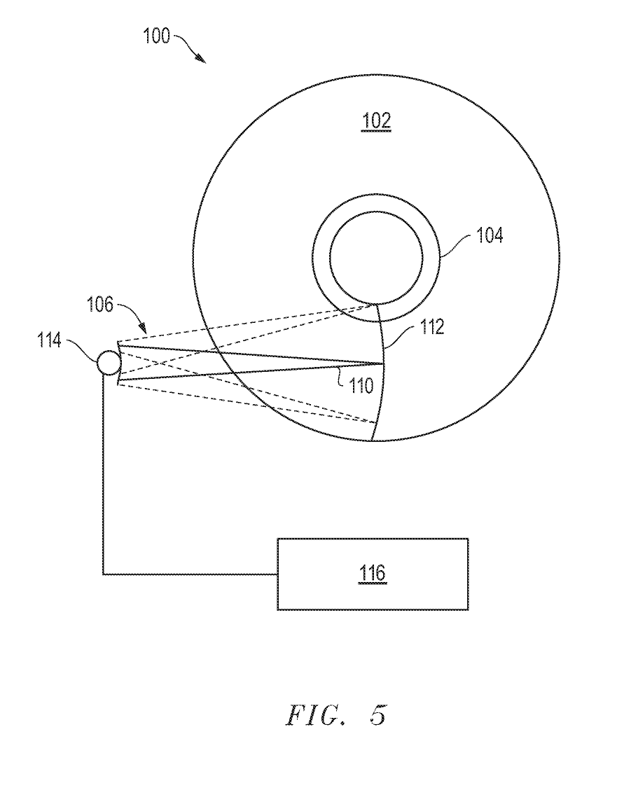

The relative thicknesses of the layers comprising the overcoat affect its tribological performance under extreme temperature and humidity stress conditions. If the SiN/SiC base layer 15 is not sufficiently covered by the top carbon overcoat layers 19, oxidation of the SiN/SiC to SiOₓ can occur. The SiOₓ can accumulate on the sliders 110 (FIG. 5) flying close to the surface of the disk 102, which results in a rapid deterioration of the mechanical reliability of the head/disk interface. FIG. 4 is a plot 41 that illustrates a tri-layer overcoat having a thickness of, e.g., approximately 25 Å, the thickness of the intermediate or IBD layer 17 should be greater than about 10 Å to prevent this failure mechanism. In other embodiments, the intermediate layer may have a thickness in the range of 8 to 20 Å, and the total thickness of the overcoat 11 may be in the range of about 20 to 35 Å. In still other embodiments, the top layer 19 may comprise a thickness of about 3 Å.

In some embodiments, the disk 102 for a hard disk drive 100 comprises perpendicular magnetic recording media comprising a plurality of magnetic layers 13 for recording data. The disk 102 is substantially planar and has a rotational axis. The overcoat 11 on the disk 102 has a plurality of thin film layers. In the illustrated embodiment of FIG. 1, these sub-layers include an initial layer 15 comprising a dense mixture of both SiCₓ and SiN_{y} compounds; an intermediate layer 17 of a dense high energy carbon on the initial layer; and an outer layer 19 of CNₓ on the intermediate layer. The overcoat 11 has an overall axial thickness of less than about 35 Å.

In one embodiment, the initial layer 15 is reactively-sputtered SiCₓN_{y}, is deposited using a pulsed DC power supply or RF sputtering, and the outer layer is sputtered. The intermediate layer 17 is a thin carbon layer deposited by an ion beam energy deposition process, and provides a dense barrier for prevention of oxidation of the initial layer. The intermediate layer 17 also provides carbon atoms for reacting with unbonded Si from the initial layer 15. The outer layer 19 is axially thinner than the intermediate layer 17, and is sputtered and deposited on the intermediate layer 17. The outer layer 19 provides a surface concentration of nitrogen for facilitating interaction of a topical lubricant 20 with the disk 102.

Referring to FIG. 5, a schematic diagram of a hard disk drive assembly 100 constructed in accordance with the invention is shown. A hard disk drive assembly 100 generally comprises one or more hard disks comprising a perpendicular magnetic recording media 102, rotated at high speeds by a spindle motor (not shown) during operation. The magnetic recording media 102 will be more fully described herein. Concentric data tracks 104 formed on either or both disk surfaces receive and store magnetic information.

A read/write head 110 may be moved across the disk surface by an actuator assembly 106, allowing the head 110 to read or write magnetic data to a particular track 104. The actuator assembly 106 may pivot on a pivot 114. The actuator assembly 106 may form part of a closed loop feedback system, known as servo control, which dynamically positions the read/write head 110 to compensate for thermal expansion of the perpendicular magnetic recording media 102 as well as vibrations and other disturbances. Also involved in the servo control system is a complex computational algorithm executed by a microprocessor, digital signal processor, or analog signal processor 116 that receives data address information from an associated computer, converts it to a location on the perpendicular magnetic recording media 102, and moves the read/write head 110 accordingly.

Specifically, read/write heads 110 periodically reference servo patterns recorded on the disk to ensure accurate head 110 positioning. Servo patterns may be used to ensure a read/write head 110 follows a particular track accurately, and to control and monitor transition of the head 110 from one track 104 to another. Upon referencing a servo pattern, the read/write head 110 obtains head position information that enables the control circuitry 116 to subsequently realign the head 110 to correct any detected error.

Servo patterns may be contained in engineered servo sectors 112 embedded within a plurality of data tracks 104 to allow frequent sampling of the servo patterns for optimum disk drive performance. In a typical perpendicular magnetic recording media 102, embedded servo sectors 112 extend substantially radially from the perpendicular magnetic recording media 102 center, like spokes from the center of a wheel. Unlike spokes however, servo sectors 112 form a subtle, arc-shaped path calibrated to substantially match the range of motion of the read/write head 110.

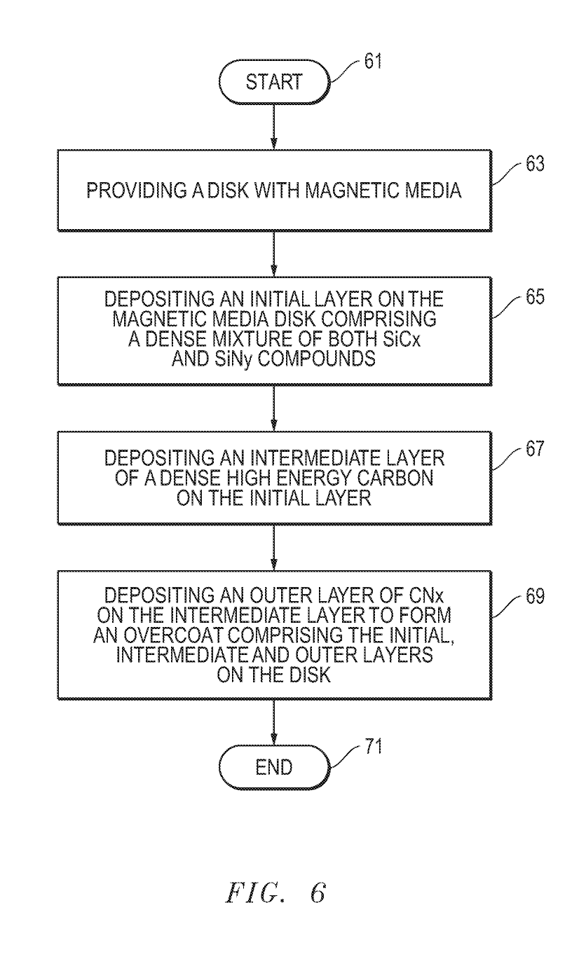

Referring now to FIG. 6, the invention also comprises a method of forming an overcoat on a disk for a hard disk drive. One embodiment of the method begins as indicated at step 61, and comprises providing a disk with magnetic media (step 63); depositing an initial layer on the magnetic media disk comprising a dense mixture of both SiCₓ and SiN_{y} compounds (step 65); depositing an intermediate layer of a dense high energy carbon on the initial layer (step 67); and depositing an outer layer of CNₓ on the intermediate layer to form an overcoat comprising the initial, intermediate and outer layers on the disk (step 69); before ending as indicated at step 71.

In other embodiments, the method comprises reacting nitrogen with sputtered silicon, the nitrogen being present as a mixture of Ar+N₂ in a sputter working gas, and SiC is formed by reaction of non-nitrided Si with carbon in the subsequently deposited intermediate layer. The method also may comprise dynamically controlling an N₂ partial pressure to affect a reactive deposition of SiN; and/or reactively-sputtering SiCₓN_{y} as the initial layer; and/or depositing the initial layer using a pulsed DC power supply or RF sputtering.

In still other embodiments, the method comprises depositing the intermediate layer as a thin carbon layer with an ion beam energy deposition process to provide a dense barrier for prevention of oxidation of the initial layer; and/or providing carbon atoms with the intermediate layer to react with unbonded Si in the initial layer; and/or providing the outer layer with a thickness that is less than a thickness of the intermediate layer, and sputtering the outer layer to provide a surface concentration of nitrogen and facilitating interaction of a topical lubricant with the disk.

This written description uses examples to disclose the invention, including the best mode, and also to enable those of ordinary skill in the art to make and use the invention. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims. While the invention has been shown or described in only some of its forms, it should be apparent to those skilled in the art that it is not so limited, but is susceptible to various changes without departing from the scope of the invention.

We claim:

1. A disk for a hard disk drive, comprising:
a disk with perpendicular magnetic recording media comprising a plurality of magnetic layers for recording data, the disk being substantially planar and having a rotational axis;
an overcoat on the disk, the overcoat having a plurality of thin film layers, comprising:
an initial layer comprising both SiCₓ and SiN_{y} compounds;
an intermediate layer of carbon on the initial layer; and
an outer layer of CNₓ on the intermediate layer.

2. A disk according to claim 1, wherein the overcoat has an overall axial thickness of less than about 35 Å.

3. A disk according to claim 1, wherein the initial layer is reactively-sputtered SiCₓN_{y}, and is deposited using a pulsed DC power supply or RF sputtering, and the outer layer is sputtered.

4. A disk according to claim 1, wherein the intermediate layer is a thin carbon layer deposited by an ion beam energy deposition process, and provides a barrier for prevention of oxidation of the initial layer.

5. A disk according to claim 1, wherein the intermediate layer provides carbon atoms for reacting with unbonded Si from the initial layer.

6. A disk according to claim 1, wherein the outer layer is axially thinner than the intermediate layer, and is sputtered and deposited on the intermediate layer, and further comprising a topical lubricant on the overcoat, such that the outer layer provides a surface concentration of nitrogen for facilitating interaction of the topical lubricant with the disk.

7. A disk according to claim 1, wherein ratios of SiCₓ to SiN_{y} are determined by fractions of Si atoms bound to C and N as determined by a characterization technique that differentiates the Si (C bound) from the Si (N bound) by analysis of Si photoelectron binding energy.

8. A disk according to claim 1, wherein the overcoat has a thickness of approximately 25 Å, and a thickness of the intermediate layer is greater than about 10 Å.

9. A disk according to claim 1, wherein the intermediate layer has a thickness in a range of 8 to 20 Å, and a total thickness of the overcoat is in a range of about 20 to 35 Å.

10. A disk according to claim 1, wherein the top layer has a thickness of about 3 Å.

11. A hard disk drive, comprising:
a disk with perpendicular magnetic recording media comprising a plurality of magnetic layers for recording data, the disk being substantially planar and having a rotational axis;
an overcoat on the disk, the overcoat having a plurality of thin film layers, comprising:
an initial layer comprising both SiCₓ and SiN_{y} compounds;
an intermediate layer of carbon on the initial layer; and
an outer layer of CNₓ on the intermediate layer; and
an actuator having a magnetic read head for reading data from the disk.

12. A hard disk drive according to claim 11, wherein the overcoat has an overall axial thickness of less than about 35 Å, the initial layer is reactively-sputtered SiCₓN_{y} and is deposited using a pulsed DC power supply or RF sputtering, and the outer layer is sputtered.

13. A hard disk drive according to claim 11, wherein the intermediate layer is a thin carbon layer deposited by an ion beam energy deposition process, provides a barrier for prevention of oxidation of the initial layer, and provides carbon atoms for reacting with unbonded Si from the initial layer.

14. A hard disk drive according to claim 11, wherein the outer layer is axially thinner than the intermediate layer, and is sputtered and deposited on the intermediate layer, and further comprising a topical lubricant on the overcoat, such that the outer layer provides a surface concentration of nitrogen for facilitating interaction of the topical lubricant with the disk.

15. A hard disk drive according to claim 11, wherein ratios of SiCₓ to SiN_{y} are determined by fractions of Si atoms bound to C and N as determined by a characterization technique that differentiates the Si (C bound) from the Si (N bound) by analysis of Si photoelectron binding energy, the overcoat has a thickness of approximately 25 Å, and a thickness of the intermediate layer is greater than about 10 Å.

16. A hard disk drive according to claim 11, wherein the intermediate layer has a thickness in a range of 8 to 20 Å, a total thickness of the overcoat is in a range of about 20 to 35 Å, and the top layer has a thickness of about 3 Å.

17. A method of forming an overcoat on a disk for a hard disk drive, comprising:
(a) providing a disk with magnetic media;
(b) depositing an initial layer on the magnetic media disk comprising both SiCₓ and SiN_{y} compounds;
(c) depositing an intermediate layer of carbon on the initial layer; and
(d) depositing an outer layer of CNₓ on the intermediate layer to form an overcoat comprising the initial, intermediate and outer layers on the disk.

18. A method according to claim 17, wherein the overcoat has an overall thickness of less than about 35 Å, and step (b) comprises reacting nitrogen with sputtered silicon, the nitrogen being present as a mixture of Ar+N₂ in a sputter working gas, and SiC is formed by reaction of non-nitrided Si with carbon in the subsequently deposited intermediate layer.

19. A method according to claim 17, wherein step (b) comprises dynamically controlling an N₂ partial pressure to affect a reactive deposition of SiN, and reactively-sputtering SiCₓN_{y} as the initial layer.

20. A method according to claim 17, wherein step (b) comprises depositing the initial layer using a pulsed DC power supply or RF sputtering, and step (c) comprises depositing the intermediate layer as a thin carbon layer with an ion beam energy deposition process to provide a barrier for prevention of oxidation of the initial layer.

21. A method according to claim 17, wherein step (c) further comprises providing carbon atoms with the intermediate layer to react with unbonded Si in the initial layer.

22. A method according to claim 17, wherein the outer layer has a thickness that is less than a thickness of the intermediate layer, and step (d) comprises sputtering the outer layer to provide a surface concentration of nitrogen and facilitating interaction of a topical lubricant with the disk.

23. A method according to claim 17, further comprising determining ratios of SiCₓ to SiN_{y} by fractions of Si atoms bound to C and N as determined by a characterization technique that differentiates the Si (C bound) from the Si (N bound) by analysis of Si photoelectron binding energy.

24. A method according to claim 17, wherein the overcoat has a thickness of approximately 25 Å, and a thickness of the intermediate layer is greater than about 10 Å.

25. A method according to claim 17, wherein the intermediate layer has a thickness in a range of 8 to 20 Å, a total thickness of the overcoat is in a range of about 20 to 35 Å, and the top layer has a thickness of about 3 Å.
